(19) United States
(12) Patent Application Publication
(10) Pub. No.: US 2012/0032153 A1
(43) Pub. Date: Feb. 9, 2012

(54) Organic Light-Emitting Diode Device

(75) Inventors: Jwo-Huei Jou, Hsinchu (TW); Po-Shien Wu, Hsinchu (TW)

(73) Assignee: NATIONAL TSING-HUA UNIVERSITY, Hsinchu (TW)

(21) Appl. No.: 13/156,407

(22) Filed: Jun. 9, 2011

(30) Foreign Application Priority Data
Aug. 5, 2010 (TW) 099126087

(51) Int. Cl. H01L 51/54; H01L 51/52

(52) U.S. Cl. 257/40; 257/E51.019; 257/E51.024

(57) ABSTRACT

The present invention relates to an improved organic light-emitting diode (OLED) device which comprises a first conductive layer, a first light-emitting material layer, a second light-emitting material layer, a second conductive layer, and at least one third light-emitting material layer, wherein the first conductive layer is adapted for being an anode substrate, moreover, by way of evaporation process, the first light-emitting material layer, the third light-emitting material layer, the second light-emitting material layer, and the second conductive layer are formed on the anode substrate in turns. Besides, the phenomenon of efficiency roll-off occurring in a high luminance region of the OLED device may be improved by adding the third light-emitting material layer between the first light-emitting material layer and the second light-emitting material layer.

### BACKGROUND OF THE INVENTION

1. Field of the Invention

The present invention relates to an organic light-emitting diode (OLED) device, and more particularly to an improved OLED device which employs a third light-emitting material layer disposed between a first light-emitting material layer and a second light-emitting material layer, so as to improve the phenomenon of efficiency roll-off occurring in a high luminance region of the OLED device.

2. Description of the Prior Art

An organic light emitting diode (OLED) was invented by C. W. Tang and S. A. VanSlyk et al. of Eastman Kodak Company in 1987 and manufactured by a vacuum evaporation method. A hole transporting material and an electron transporting material (such as Alq₃) are respectively deposited on a transparent indium tin oxide (abbreviated as ITO) glass, and then a metal electrode is vapor-deposited thereon to form the self-luminescent OLED apparatus. Due to high brightness, fast response speed, light weight, compactness, true color, no difference in viewing angles, no need of liquid crystal display (LCD) type backlight plates as well as a saving in light sources and low power consumption, it has become a new generation display.

Besides light-emitting material layers, the conventional OLED device is often added to other intermediate layers, such as an electron transport layer and a hole transport layer, so as to enhance the efficiency of the OLED device. Referring to FIG. 1, which is a structural drawing of a conventional OLED device. As shown in FIG. 1, the conventional OLED device 1′ includes a cathode 11′, an electron injection layer 12′, an electron transport layer 13′, a first light-emitting material layer 14′, a second light-emitting material layer 15′, a hole transport layer 16′, a hole injection layer 17′, and an anode 18′.

The above-mentioned conventional OLED device 1′ is an OLED device with high efficiency. However, referring to FIG. 2, which is a curve diagram of the luminous efficiency of the conventional OLED device 1′. As shown in FIG. 2, when the brightness of the conventional OLED device 1′ is higher than 3500 cd/m², the luminous efficiency of the conventional OLED device 1′ is decreased rapidly. Such a phenomenon is called an Efficiency Roll-Off phenomenon of the conventional OLED device 1′.

In view of this, it is necessary to provide a novel OLED device to improve the above shortcomings and insufficiencies.

### SUMMARY OF THE INVENTION

The major objective of the present invention is to provide an improved organic light-emitting diode (OLED) device, which adds a mixed emitting layer having a thickness less than 10 nm between two light-emitting material layers, so as to improve the Efficiency Roll-Off phenomenon happened in the high-brightness area of the conventional OLED device.

According to the above objective, the present invention provides an improved organic light-emitting diode (OLED) device comprising: a first conductive layer; a first light-emitting material layer being disposed on the first conductive layer; a second light-emitting material layer being disposed on the first light-emitting material layer; a second conductive layer being disposed on the second light-emitting material layer; and at least one third light-emitting material layer being disposed between the first light-emitting material layer and the second light-emitting material layer.

### BRIEF DESCRIPTION OF THE DRAWINGS

For a complete understanding of the aspects, structures and techniques of the invention, reference should be made to the following detailed description and accompanying drawings wherein:

FIG. 1 is a structural drawing of a conventional OLED device;

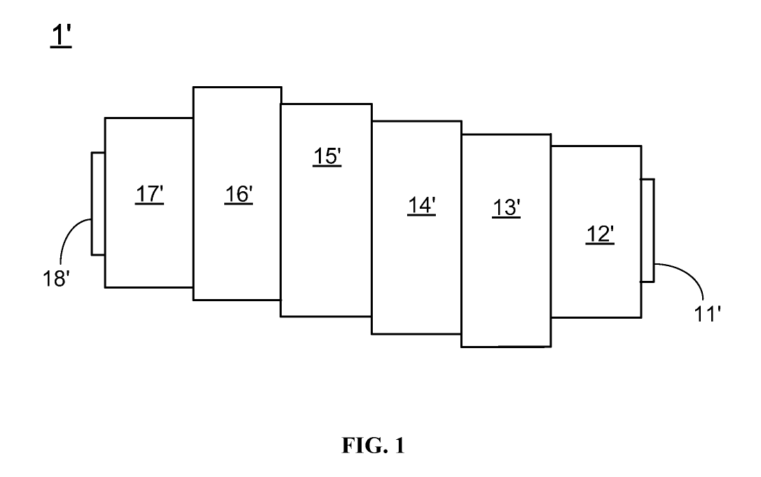

FIG. 2 is a curve diagram of the luminous efficiency of the conventional OLED device;

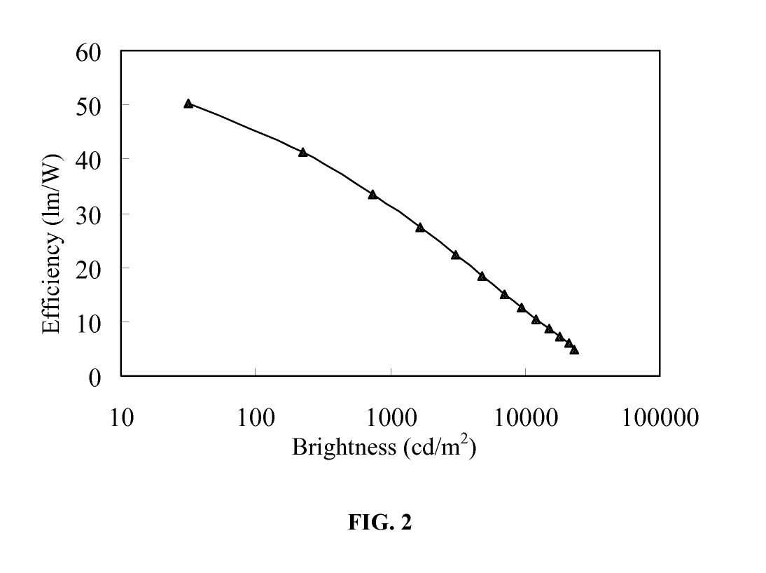

FIG. 3 is a structural drawing of an improved OLED device of the present invention;

FIG. 4 is a curve diagram of the luminous efficiency of the improved OLED device of the present invention; and

FIG. 5 is a second curve diagram of the luminous efficiency of the improved OLED device of the present invention.

### DETAILED DESCRIPTION OF THE PREFERRED EMBODIMENTS

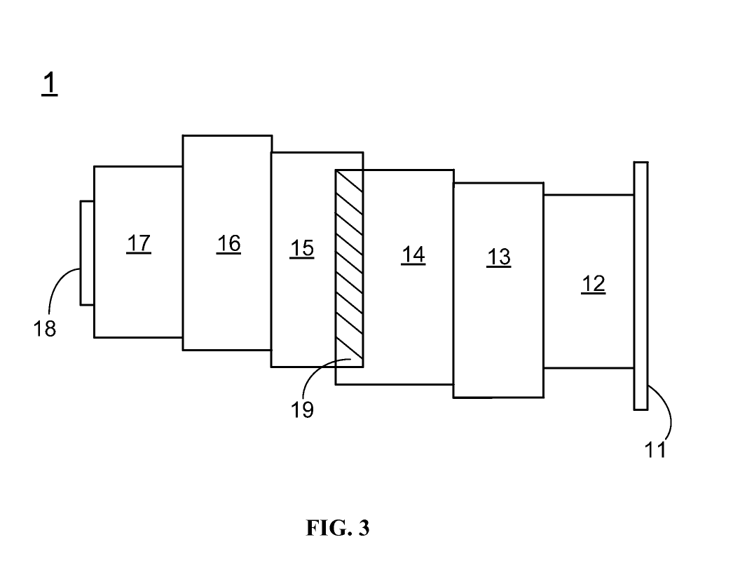

Referring to FIG. 3, which is a structural drawing of an improved OLED device of the present invention. As shown in FIG. 3, the improved OLED device 1 includes a first conductive layer 11, a hole injection layer 12, a hole transport layer 13, a first light-emitting material layer 14, a second light-emitting material layer 15, an electron transport layer 16, an electron injection layer 17, a second conductive layer 18, and a third light-emitting material layer 19. The first conductive layer 11 is an anode of the improved OLED device 1, and the material of the first conductive layer 11 is ITO. The hole injection layer 12, the hole transport layer 13, the first light-emitting material layer 14, the third light-emitting material layer 19, the second light-emitting material layer 15, the electron transport layer 16, the electron injection layer 17, and the second conductive layer 18 are formed on the ITO sequentially.

The hole injection layer 12 is formed on the first conductive layer 11 by a spin-coating process. Preferably, the material of the hole injection layer 12 is PEDOT:PSS (poly(ethylene-dioxythiophene):poly(styrene sulfonic acid)). The hole transport layer 13 is formed of the hole injection layer 12 by an evaporation deposition process, and the material of the hole transport layer 13 is TAPC (1,1-bis {4-[di(p-tolyl)amino]-phenyl}cyclohexane).

Continuously referring to FIG. 3, the above first light-emitting material layer 14 is formed on the hole transport layer 13 by the evaporation deposition process, and the material of the first light-emitting material layer 14 is TCTA (4,4′,4′-tris (9-carbazolyl) triphenylamine). Further, in order to make the first light-emitting material layer 14 emit a light with a specific color, the first light-emitting material layer 14 can be doped with a dopant, such as Ir(2-phq)3(Tris(2-phenylquinoline) iridium(III)).

The third light-emitting material layer 19 is formed on the first light-emitting material layer 14 by the evaporation deposition process, and the second light-emitting material layer 15 is formed on the third light-emitting material layer 19. The material of the second light-emitting material layer 15 is TPBi (2-2′-2″-(1,3,5-benzinetriyl)tris(1-phenyl-1-H-benzimidazole)). In order to make the second light-emitting material layer 15 emit a light with a specific color, the second light-emitting material layer 15 can be doped with a dopant, such as Ir(2-phq)3 (Tris(2-phenylquinoline) iridium(III)). In the present invention, the third light-emitting material layer 19 is formed by mixing part of the first light-emitting material layer 14 and part of the second light-emitting material layer 15, and the thickness of the third light-emitting material layer 19 should be less than 10 nm. In a preferred embodiment of the present invention, the thickness of the third light-emitting material layer 19 is 5 nm, and the material of the thickness of the third light-emitting material layer 19 includes TCTA, TPBi and Ir(2-phq)3.

Continuously referring to FIG. 3, the electron transport layer 16 is formed on the second light-emitting material layer 15 by the evaporation deposition process, and the material of the electron transport layer 16 is Bphen (bathophenanthroline). The electron injection layer 17 is formed on the electron transport layer 16 by the evaporation deposition process, and the material of the electron injection layer 17 is LiF. Finally, the second conductive layer 18 is formed on the electron injection layer 17 by the evaporation deposition process, and the material of the second conductive layer 18 is Al. In the improved OLED device of the present invention, the second conductive layer 18 is a cathode.

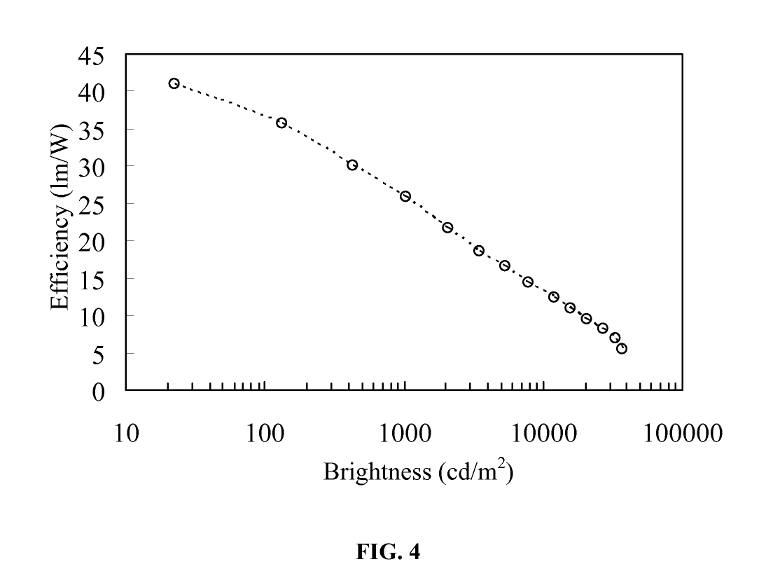

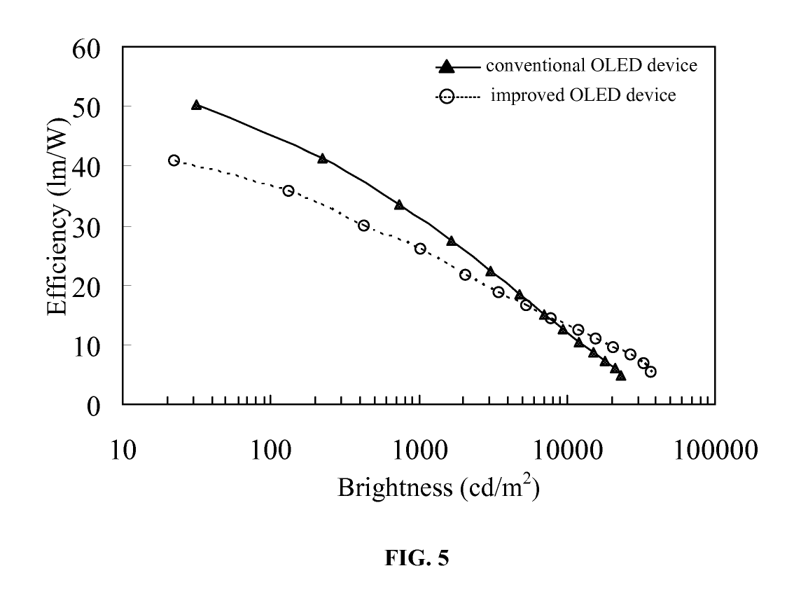

Referring to FIG. 4, which is a curve diagram of the luminous efficiency of the improved OLED device of the present invention. As shown in FIG. 4, when the brightness of the improved OLED device of the present invention is about 3500 cd/m², the luminous efficiency still remains in 19 lm/W. Referring to FIG. 5, which is a second curve diagram of the luminous efficiency of the improved OLED device of the present invention. As shown in FIG. 5, the solid curve with solid triangles represents the luminous efficiency of the conventional OLED device; the dashed curve with hollow circles represents the luminous efficiency of the improved OLED device of the present invention. Wherein when the brightness of the OLED devices exceed 3500 cd/m², the solid curve and the dashed curve begin to decline. However, when the brightness is about 10000 cd/m², the hollow circles on the dashed curve are higher than the solid triangles on the solid curve. It can be seen from this that the Efficiency Roll-off phenomenon in the high-brightness area of the improved OLED device 1 of the present invention is improved greatly compared to the conventional OLED device.

By the detailed description of the overall structure and technical content of the present invention, the following advantages of the present invention can be derived:

1. By adding the third light-emitting material layer between the first light-emitting material layer and the second light-emitting material layer, and adjusting the thickness of the third light-emitting material layer, the Efficiency Roll-off phenomenon in the high-brightness area of the OLED device can be greatly improved.

2. The third light-emitting material layer is formed by mixing part of the first light-emitting material layer and part of the second light-emitting material layer, thus the problem of discontinuous interface between different materials is not to be considered when the third light-emitting material layer is formed.

3. The present invention applies the first conductive layer as the anode, and the hole injection layer, the hole transport layer, the first light-emitting material layer, the third light-emitting material layer, the second light-emitting material layer, the electron transport layer, the electron injection layer, and the second conductive layer are formed on the anode sequentially by the evaporation deposition process, it does not require other difficult process, so as to contribute to the mass production of the improved OLED device of the present invention.

It should be understood that the embodiments of the present invention described herein are merely illustrative of the technical concepts and features of the present invention and are not meant to limit the scope of the invention. Those skilled in the art, after reading the present disclosure, will know how to practice the invention. Various variations or modifications can be made without departing from the spirit of the invention. All such equivalent variations and modifications are intended to be included within the scope of the invention.

As a result of continued thinking about the invention and modifications, the inventors finally work out the designs of the present invention that has many advantages as described above. The present invention meets the requirements for an invention patent, and the application for a patent is duly filed accordingly. It is expected that the invention could be examined at an early date and granted so as to protect the rights of the inventors.

What is claimed is:

1. An improved organic light-emitting diode (OLED) device comprising:
a first conductive layer;
a first light-emitting material layer being disposed on the first conductive layer;
a second light-emitting material layer being disposed on the first light-emitting material layer;
a second conductive layer being disposed on the second light-emitting material layer; and
at least one third light-emitting material layer being disposed between the first light-emitting material layer and the second light-emitting material layer.

2. The improved OLED device according to claim 1, further comprising a hole transport layer disposed between the first conductive layer and the first light-emitting material layer.

3. The improved OLED device according to claim 2, further comprising a hole injection layer disposed between the first conductive layer and the hole transport layer.

4. The improved OLED device according to claim 1, further comprising an electron transport layer disposed between the second light-emitting material layer and the second conductive layer.

5. The improved OLED device according to claim 4, further comprising an electron injection layer disposed between the electron transport layer and the second conductive layer.

6. The improved OLED device according to claim 1, wherein the material of the first conductive layer is Indium Tin Oxide (ITO).

7. The improved OLED device according to claim 3, wherein the material of the hole injection layer is PEDOT:PSS (poly(ethylenedioxythiophene): poly(styrene sulfonic acid)).

8. The improved OLED device according to claim 2, wherein the material of the hole transport layer is TAPC (1,1-bis{4-[di(p-tolyl)amino]-phenyl}cyclohexane).

9. The improved OLED device according to claim 1, wherein the material of the first light-emitting material layer is TCTA (4,4′,4″-tris (9-carbazolyl) triphenylamine).

10. The improved OLED device according to claim 5, wherein the first light-emitting material layer further contains a dye material: Ir(2-phq)3 (Tris(2-phenylquinoline)iridium(III)).

11. The improved OLED device of claim 1, wherein the material of the second light-emitting material layer is TPBi (2-2′ -2″-(1,3,5-benzinetriyl)tris(1-phenl-1-H-benzimidazole)).

12. The improved OLED device of claim 7, wherein the second light-emitting material layer further contains a dye material: Ir(2-phq)3 (Tris(2-phenylquinoline)iridium(III)).

13. The improved OLED device according to claim 4, wherein the material of the electron transport layer is Bphen (bathophenanthroline).

14. The improved OLED device according to claim 5, wherein the material of the electron injection layer is LiF.

15. The improved OLED device according to claim 1, wherein the material of the second conductive layer is Al.

16. The improved OLED device according to claim 1, wherein the third light-emitting material layer is formed by mixing part of the first light-emitting material layer and part of the second light-emitting material layer.

17. The improved OLED device according to claim 1, wherein the thickness of the third light-emitting material layer is less than 10 nm.
